(19) United States
(12) Patent Application Publication
(10) Pub. No.: US 2009/0286014 A1
(43) Pub. Date: Nov. 19, 2009

(54) PHOTOLUMINESCENT COMPOSITION AND METHOD

(75) Inventor: David Scherer, Pagosa Springs, CO (US)

Correspondence Address: BRIGGS AND MORGAN P.A., 2200 IDS CENTER, 80 SOUTH 8TH ST, MINNEAPOLIS, MN, 55402, US

(73) Assignee: Ghost Eye Products LLC, Pagosa Springs, CO (US)

(21) Appl. No.: 12/425,973

(22) Filed: Apr. 17, 2009

Related U.S. Application Data
(60) Provisional application No. 61/127,988, filed on May 19, 2008.

(51) Int. Cl. C09K 11/56; C09K 11/54; C23C 14/28

(52) U.S. Cl. 427/595; 252/301.4 S; 252/301.6 S

(57) ABSTRACT

A mixed powder composition is of approximately 25% photoluminescent pigment and 75% binder. The photoluminescent pigment may include chemically doped metal sulfides, alkaline earth metal aluminates or alkaline earth metal silicates that are activated by light and generate a long after glow of light that glows in the darkness for many hours. The photoluminescent pigments are carried by a binder mix such as drywall mix (mineral gypsum) or plaster of Paris (calcium sulfate semihydrate). The powder is sprayable from a bottle with a nozzle onto tree bark, rocks or the ground. As the powder absorbs moisture, it becomes hard to last for months. The photoluminescent pigments in the soft or hardened powder absorbs sunlight or ultraviolet light from a flashlight to emit a long after glow to assist the user in navigating in the dark wilderness.

### CROSS-REFERENCE TO RELATED APPLICATION

The present application is based on and claims the benefit of U.S. provisional patent application Ser. No. 61/127,988, filed May 19, 2008, the content of which is hereby incorporated by reference in its entirety.

### BACKGROUND OF THE INVENTION

The present invention relates to a method and a composition for marking trails in the wilderness, and more particularly to a method and a composition for photoluminescently marking trails to prevent the user in the nighttime from becoming lost or to assist the user in following a trail to get to a predetermined point in the wilderness in darkness.

Human beings have two types of nerve cells in their eyes. Color is differentiated by eye cone nerve cells. Rod nerve cells differentiate black and white and are predominately used in night time navigation. Humans have many more cone cells than rod cells, Alternatively, animals' eyes are largely composed of rod cells. Human beings have traditionally moved about in the night time wilderness with flashlights to locate and stay on trails to prevent from becoming lost. However flashlights can spook big game, give the location of humans to wildlife and alert wildlife to potential danger.

Human beings have used reflectors to mark their trails but such reflectors require the use of flashlights. Trail lights have been used to mark trails however such lights require batteries which can be exhausted in a short time and render the trail lights ineffective.

There is a need for a long lasting, sunlight charging, photoluminescent trail marking composition and method that will assist the outdoorsman and hunter in navigating through the dark wilderness to find their way and to locate game and trails without the need for bright flashlights.

### SUMMARY OF THE INVENTION

A mixed powder composition is of approximately 25% photoluminescent pigment and 75% binder. The photoluminescent pigment may include chemically doped metal sulfides, alkaline earth metal aluminates or alkaline earth metal silicates that are activated by light and generate a long after glow of light that glows in the darkness for many hours. The photoluminescent pigments are carried by a binder mix such as drywall mix (mineral gypsum) or plaster of Paris (calcium sulfate hemihydrate). The powder is sprayable from a bottle with a relatively open nozzle onto tree bark, rocks or the ground. As the powder absorbs moisture, it becomes hard to last for months. The photoluminescent pigments in the soft or hardened powder absorbs sunlight or ultraviolet light from a flashlight to emit a long after glow to assist the user in navigating in the dark wilderness.

A principal object and advantage of the present invention is the elimination of traditional flashlights to find one's way in the night time wilderness.

Another object and advantage of the invention is the moisture absorbent mixed powder composition with binder will harden after exposure to any form of moisture including dew, frost, rain, snow, fog or mist to render the photoluminescent pigment secured to the article upon which they were sprayed.

Another object and advantage of the invention is that the photoluminescent pigment of the composition will be charged by daylight enabling the user to move about the night time wilderness without a flashlight but with the light emittance from the photoluminescent composition.

Another object and advantage of the present invention is that the photoluminescent particles maybe supplementally charged by ultraviolet (UV) light from a regular flashlight or a UV flashlight.

Another Object and advantage of the invention is that the composition poses no environmental risk to nature whatsoever.

Another object and advantage is the composition is simple to use by just spraying the powder composition out of the bottle's nozzle on the object to be marked for glowing.

Another object and advantage is the composition may be mixed with water to create a liquid or paste which may be sprayed, painted or smeared onto desired objects.

Another object and advantage of the present invention is that it can be used for hunting, hiking, camping, mountain biking or cave exploration by the user or others to follow in the dark.

### BRIEF DESCRIPTION OF THE DRAWINGS

FIG. 1 is a perspective view of the spray bottle for carrying and dispensing the photoluminescent composition;

FIG. 2 is an alternative bottle cap;

FIG. 3 is a brush applicator; and

FIG. 4 is an environmental view of the method of strategically dispensing the photoluminescent composition.

### DETAILED DESCRIPTION OF INVENTION

The term photoluminescent is used to describe the light generating composition component of the present invention. Phosphorescent is another term that generally means a material that is activated with light energy and then releases a long “after glow” when the material is then moved to the dark (i.e. “glow in the dark”). The term fluorescent refers to materials that release light so quickly that there is no afterglow (e.g. blaze orange hunting vests). The more technical definition of phosphorescence is a change of quantum mechanical spin states in molecules going through light emission. Fluorescent molecules maintain their quantum mechanical spin state. It is highly likely that most “glow in the dark” pigments are phosphorescent but, there are some reports of fluorescent materials with a long decay time. Luminescent is the blanket term for both phosphorescent and fluorescent materials (i.e. the term “guns” covers both “rifles” and “pistols”). Photoluminescent implies activation by light.

There are a variety of formulations that could possibly be used as the photoluminescent pigment component. The bulk of these have chemical dopants. A dopant is a trace amount of chemical that is added to a bulk substance to change the overall properties of the material. A colon is used in the molecular formula of a photoluminescent substance to depict a dopant. For example:

ZnS:Cu

This formula describes Zinc sulfide that is doped with copper. Those who are practiced in the art would know that copper is doped in a quantity that is less than 1% the mass of ZnS. However, Zinc sulfide doped with 1.2% Cu might still be photoluminescent.

Photoluminescent materials or pigments may be purchased from United Mineral & Chemical Corporation (UMC) of Lyndhurst, N.J.

One photoluminescent pigment in the composition preferably may be copper doped zinc sulfide. The chemical formula is ZnS:Cu. This and other UMC products are in Table 1.

TABLE 1
UMC's Phosphorescent Products

| | Photo- | | | |
|---|---|---|---|---|
| | luminescent | Photo- | | |
| | component | luminescent | Coloring | |
| UMC part # | name | formula | Additive | Comments |
| 6SSU | Copper doped | ZnS:Cu | none | The |
| | zinc sulfide | | | brightest |
| | | | | ZnS formula |
| GSS series | Copper doped | ZnS:Cu | fluorescent | fluorescent |
| | zinc sulfide | | pigments | pigments |
| | | | added | lower |
| | | | | brightness |
| GSR | Copper and | ZnS:Cu, Mg | none | |
| | manganese | | | |
| | doped zinc | | | |
| | sulfide | | | |
| GSR 115/2 | Copper and | ZnS:Cu, Mg | fluorescent | fluorescent |
| | manganese | | pigments | pigments |
| | doped zinc | | added | lower |
| | sulfide | | | brightness |
| BAS series | Bismuth doped | CaSrS:Bi | none | |
| | calcium | | | |
| | strontium | | | |
| | sulfide | | | |
| BAS 5025/1 | Bismuth doped | CaSrS:Bi | fluorescent | fluorescent |
| | calcium | | pigments | pigments |
| | strontium | | added | lower |
| | sulfide | | | brightness |

General description of photoluminescent pigments usable with this invention are in Table 2. This listing will also include the UMC products shown organized from Table 1 and some formulas that are brought up in the literature with “long afterglow”.

TABLE 2
Photoluminescent Materials

| | | Examples of | | |
|---|---|---|---|---|
| General | General | general | | |
| Grouping | formula | formula | Mixtures | Examples of Mixtures |
| Doped | MS:D | ZnS:Cu | M₁M₂S:D₁,D₂ | CaSrS:Bi |
| Metal | Where M is | CaS:Bi | Where M1 and M2 | ZnCdS:Cu |
| Sulfide | metal ions | | can be different | ZnS:Mn,Cu |
| | (Mg2+, Ca²⁺, | | metal ions | |
| | Sr²⁺, Ba²⁺, | | (Mg2+, Ca²⁺, Sr²⁺, | |
| | Zn²⁺, Cd²⁺) | | Ba²⁺, Zn²⁺, Cd²⁺) | |
| | and D is | | and D₁ and D₂ can | |
| | dopant (Cu²⁺, | | be different dopants | |
| | Bi²⁺, Nd³⁺, | | (Cu²⁺, Bi²⁺, Nd³⁺, | |
| | Eu³⁺, Dy³⁺) | | Eu³⁺, Dy³⁺) | |
| Doped | MAl₂O₄:D | SrAl₂O₄:Eu | M1M2Al₂Oₓ:D1,D2 | CaSrAl₂O₄:Eu |
| Alkaline | Where M is | SrAl₂O₄:Dy | Where M1 and M2 | CaAl₂O₄:Eu,Nd |
| Earth Metal | (Mg2+, Ca²⁺, | CaAl₂O₄ | can be different | SrAl₂O₄:Eu,Nd |
| Aluminate | Sr²⁺, Ba²⁺, | | metal ions | SrAl₂O₄:Eu,Dy |
| | Zn²⁺, Cd²⁺) | | (Mg2+, Ca²⁺, Sr²⁺, | |
| | and D is | | Ba²⁺, Zn²⁺, Cd²⁺), x | |
| | dopant (Cu²⁺, | | is the appropriate | |
| | Bi²⁺, Nd³⁺, | | oxide stoichiometry, | |
| | Eu³⁺, Dy³⁺) | | and D₁ and D₂ can | |
| | | | be different dopants | |
| | | | (Cu²⁺, Bi²⁺, Nd³⁺, | |
| | | | Eu³⁺, Dy³⁺) | |
| Doped | MSi₂Oₓ:D | CaMgSi₂O₅:Dy | M1M2SiOₓ:D1,D2 | SrMgSi₂O₆:Eu,Dy |
| Alkaline | Where M is | Sr₂MgSi₂O₇:Eu | Where M1 and M2 | Sr₂MgSi₂O₇:Eu,Dy |
| Earth Metal | (Mg2+, Ca²⁺, | SrMgSi₂O₆:Eu | can be different | |
| Silicate | Sr²⁺, Ba²⁺, | | metal ions | |
| | Zn²⁺, Cd²⁺), x | | (Mg2+, Ca²⁺, Sr²⁺, | |
| | is the | | Ba²⁺, Zn²⁺, Cd²⁺), x | |
| | appropriate | | is the appropriate | |
| | oxide | | oxide stoichiometry, | |
| | stoichiometry, | | and D1 and D2 can | |
| | and D is | | be different dopants | |
| | dopant (Cu²⁺, | | (Cu²⁺, Bi²⁺, Nd³⁺, | |
| | Bi²⁺, Nd³⁺, | | Eu³⁺, Dy³⁺) | |
| | Eu³⁺, Dy³⁺) | | | |
| Mixed from | | | | MgAl₂O₄SiO₂:Mn,Eu |
| Above | | | | Al₂O₃SrCO₃TiO₂:Eu,Dy |
| groups | | | | Al₂O₃SrO:Eu,Dy |

Many photoluminescent materials are mixed with fluorescent chemicals to change the color of the light emitted from the mixture. This does lead to a loss of emitted photoluminescent energy and thus, brightness in the product. Table 3, below describes some of these additives.

TABLE 3
Examples of fluorescent compounds that can be mixed
with photo-luminescent materials to give a different
appearance of color.

| | Chemical | | |
|---|---|---|---|
| | Abstract Service | Molecular | |
| Name | Registry Number | Formula | Comments |
| Acid Blue 9 | [3844-45-9] | C₃₇H₃₄N₂Na₂O₉S₃ | Can impart |
| | | | blue color |
| Fluorescein | [2321-07-5] | C₂₀H₁₂O₅ | Can impart |
| | | | yellow/green |
| | | | color |
| Rhodamine WT | [37299-86-8] | C₂₉H₂₉N₂Na₂O₅Cl | Can impart |
| | | | red color |

The binder mix intended to carry and hold the photoluminescent pigment together after being subjected to moisture. A suitable binder mix may be of drywall mix (mineral gypsum), plaster of Paris (calcium sulfate hemihydrate). The powder is sprayable from a bottle with a nozzle onto tree bark, rocks or the ground. The powder absorbs moisture and becomes hard and secure to the object sprayed to last for months.

Drywall mix is made from the mineral gypsum. Both gypsum and plaster of Paris are formed from calcium sulfate dihydrate (chemical formula CaSO₄.2H₂O). The percentages of binder mix to photoluminescent particles may vary depending on the desired use and longevity of the application. The inventor has found the 25% by weight of photoluminescent particles to 75% Binder mix works well. However the range may be 12.5% to 87.5% luminescent particles to 87.5% to 12.5% binder mix, respectively.

In addition to the drywall mix and plaster of Paris, plant based powders could be used as a binder. This would include extracts from wheat, soybean, potatoes or rice that are dried and can be reconstituted in water as a sticky semi-water proof material. These pastes form from interactions of carbohydrates and proteins in the material when mixed with water and heated. Animal collagen (gelatin) can also added to these materials to facilitate forming a natural polymeric material. Dried forms of these materials can be used as the binder material that is mixed with the photoluminescent component of the product.

Liquid binders can be mixed with photoluminescent materials and the resulting suspensions or mixtures can be applied as sprays. These liquid suspensions might be water based, water glass, hydrocarbon suspensions, or polymeric.

Water based carriers might include an emulsifier that is able to suspend the photoluminescent pigment in water for spray applications. Emulsifiers such as polyols, ethoxylated fatty acids, alkyl amines, or polyetheramines may be used.

Water glass (sodium metasilicate) can also be used in aqueous mixtures to suspend and apply photoluminescent particles. Upon drying the water glass makes a hard transparent shell that protects the photoluminescent particles within.

Hydrocarbon suspension can be used to apply the paint. Volatile components (propane, heptane, and mineral spirits) are able to evaporate leaving behind a residue of other materials (1-Methoxy-2-propanol acetate, naptha, Stoddard solvent, calcium carbonate filler) that bind and protect photoluminescent component.

Polymeric mixtures can also be used to apply product as a spray. In these formulations photoluminescent components are suspended in polymers, along with the appropriate solvent, and the mixture is applied as a spray. As the mixtures dry, they form a transparent protective coat for the photoluminescent components they contain. Acrylic polymers, polyureas, polyvinylacetates, acrylic, and polystyrene polymers could all be used for this application. These polymers can also be applied in mixtures to obtain a desired property.

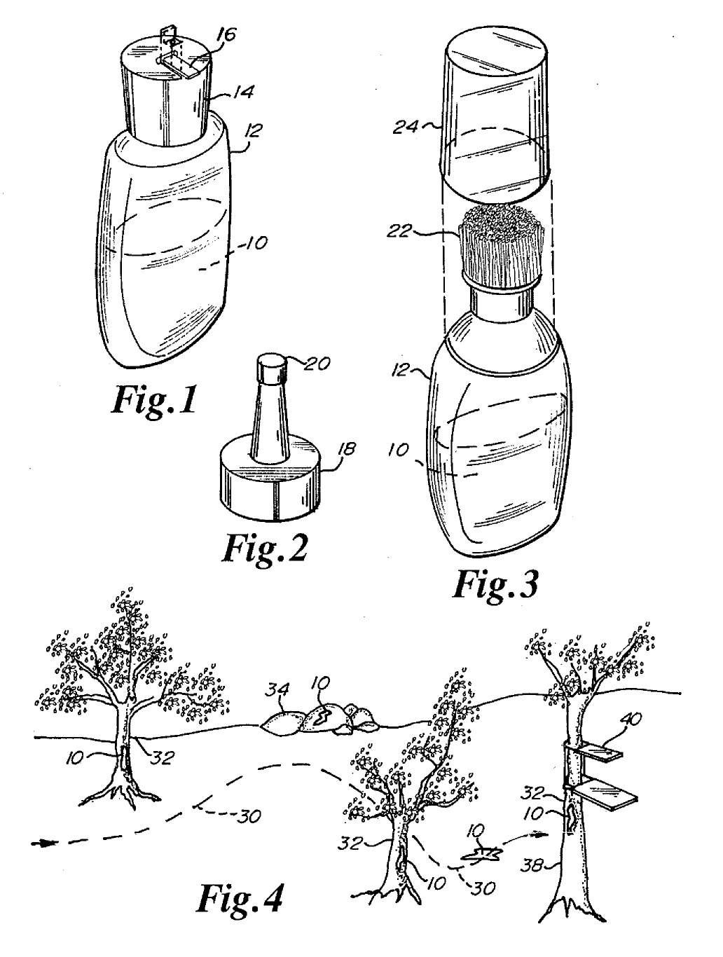

Referring to FIGS. 1 through 4, the operation the photoluminescent composition may be appreciated. The composition 10 is prepared by traditionally mixing the selected photoluminescent pigment in the desired ratio with the chosen binder mix and loaded into a dispensing bottle 12 with a cap 14 having a spout or nozzle 16. Alternate style caps 18 may include an integral nozzle and a nozzle cap 20.

The user may take the bottle 12 with him as he is about to venture into the wilderness. The powdery composition 10 is sprayed out of the nozzle 16 onto tree bark 32, rocks 34, the path 30 itself and the final destination location or tree 38 with perhaps a tree stand 40 therein.

The ratios of photoluminescent pigments to binder mix my vary with the particular application. For instance, more binder mix may be used to increase the longevity of the photoluminescent composition 10 remaining in position. One must be careful to have enough pigment in the composition for it to effectively glow. A stronger glow will be obtained with a higher ratio of photoluminescent pigment to binder mix but may not have the longevity as it may wear more easily. This may be desirable however.

In an alternative use, the photoluminescent composition may be mixed with water to create a liquid or paste which may be sprayed, painted or smeared onto desired objects. FIG. 3 illustrates a brush applicator 22 with a cap 24.

The intended scope of this invention is to be understood from the following claims as the above specification is for illustrative purposes only.

What is claimed is:

1. A photoluminescent composition for marking trails and the like in the wilderness to glow in the dark for nighttime wilderness orientation, comprising:
a) a photoluminescent pigment chosen from a group of chemically doped metal sulfides, alkaline earth metal aluminates and alkaline earth metal silicates; and
b) a binder hardenable with moisture mixed with the photoluminescent pigment.

2. The photoluminescent composition of claim 1, wherein the photoluminescent pigment is in a range of 12.5% to 87.5% by weight to the binder mix having a range of 87.5% to 12.5% by weight, respectively.

3. The photoluminescent composition of claim 1, wherein the photoluminescent pigment is approximately 25% by weight and the binder mix is approximately 75% by weight.

4. The photoluminescent composition of claim 1, wherein the photoluminescent pigment is represented by a formula of M1S:D1 or the mixed metal analogue M1M2S:D1,D2 wherein M1 and M2 are different metal ions chosen from a group comprising Mg2+, Ca²⁺, Sr²⁺, Ba²⁺, Zn²⁺ and Cd²⁺ and wherein D1 and D2 can be different dopants chosen from a group comprising Cu²⁺, Bi²⁺, Nd³⁺, Eu³⁺ and Dy³⁺.

5. The photoluminescent composition of claim 1, wherein the photoluminescent pigment is represented by a formula of M1Al₂O₄:D1 or the mixed metal analogue M₁M₂Al₂Oₓ:D1,D2 wherein M1 and M2 are different metal ions chosen from a group comprising Mg2+,Ca²⁺, Sr²⁺, Ba²⁺, Zn²⁺ and Cd²⁺ and wherein x is the appropriate oxide stoichiometry, and wherein D1 and D2 can be different dopants chosen from a group comprising Cu²⁺, Bi²⁺, Nd³⁺, Eu⁺ and Dy³⁺.

6. The photoluminescent composition of claim 1, wherein the photoluminescent pigment is represented by a formula chosen from a group comprising M1Si₂Oₓ:D or the mixed metal analogue M1M2Si₂Oₓ:D1,D2 wherein M1 and M2 are different metal ions chosen from a group comprising Mg2+,Ca²⁺, Sr²⁺, Ba²⁺, Zn²⁺ and Cd²⁺ and wherein x is the appropriate oxide stoichiometry and wherein D1 and D2 can be different dopants chosen from a group comprising Cu²⁺, Bi²⁺, Nd³⁺, Eu³⁺ and Dy³⁺.

7. The photoluminescent composition of claim 1, wherein the binder mix is chosen from a group comprising drywall mix (mineral gypsum) and plaster of Paris (calcium sulfate hemihydrate).

8. The photoluminescent composition of claim 1, wherein the binder mix is chosen from a group comprising calcium sulfate hemihydrate (CaSO₄.0.5H₂O) and mineral gypsum.

9. A photoluminescent composition for marking trails and the like in the wilderness to glow in the dark for night time wilderness orientation, comprising:
a) a photoluminescent pigment is represented by a formula of M1S:D1 or the mixed metal analogue M1M2S:D1,D2 wherein M1 and M2 are different metal ions chosen from a group comprising Mg2+, Ca²⁺, Sr²⁺, Ba²⁺, Zn²⁺ and Cd²⁺ and wherein D1 and D2 can be different dopants chosen from a group comprising Cu²⁺, Bi²⁺, Nd³⁺, Eu³⁺ and Dy³⁺.
b) a binder hardenable with moisture mixed with the photoluminescent pigment chosen from a group comprising drywall mix (mineral gypsum) and plaster of Paris (calcium sulfate hemihydrate).

10. The photoluminescent composition of claim 9, wherein the photoluminescent pigment is in a range of 12.5% to 87.5% by weight to the binder mix having a range of 87.5% to 12.5% by weight, respectively.

11. The photoluminescent composition of claim 9, wherein the photoluminescent pigment is approximately 25% by weight and the binder mix is approximately 75% by weight.

12. A photoluminescent composition for marking trails and the like in the wilderness to glow in the dark for night time wilderness orientation, comprising:
a) a photoluminescent pigment is represented by a formula of M1Al₂O₄:D1 or the mixed metal analogue M₁M₂Al₂Oₓ:D1,D2 wherein M1 and M2 are different metal ions chosen from a group comprising Mg2+, Ca²⁺, Sr²⁺, Ba²⁺, Zn²⁺ and Cd²⁺ and wherein x is the appropriate oxide stoichiometry, and wherein D1 and D2 can be different dopants chosen from a group comprising Cu²⁺, Bi²⁺, Nd³⁺, Eu³⁺ and Dy³⁺.
b) a binder hardenable with moisture mixed with the photoluminescent pigment chosen from a group comprising drywall mix (mineral gypsum), plaster of Paris (calcium sulfate semihydrate).

13. The photoluminescent composition of claim 12, wherein the photoluminescent pigment is in a range of 12.5% to 87.5% by weight to the binder mix having a range of 87.5% to 12.5% by weight, respectively.

14. The photoluminescent composition of claim 12, wherein the photoluminescent pigment is approximately 25% by weight and the binder mix is approximately 75% % by weight.

15. A photoluminescent composition for marking trails and the like in the wilderness to glow in the dark for night time wilderness orientation, comprising:
a) a photoluminescent pigment is represented by a formula chosen from a group comprising M1Si₂Oₓ:D or the mixed metal analogue M1M2Si₂Oₓ:D1,D2 wherein M1 and M2 are different metal ions chosen from a group comprising Mg2+, Ca²⁺, Sr²⁺, Ba²⁺, Zn²⁺ and Cd²⁺ and wherein x is the appropriate oxide stoichiometry and wherein D1 and D2 can be different dopants chosen from a group comprising Cu²⁺, Bi²⁺, Nd³⁺, Eu³⁺ and Dy³⁺.
b) a binder hardenable with moisture mixed with the photoluminescent pigment chosen from a group comprising calcium sulfate hemihydrate (CaSO₄.0.5H₂O).

16. The photoluminescent composition of claim 15, wherein the photoluminescent pigment is in a range of 12.5% to 87.5% by weight to the binder mix having a range of 87.5% to 12.5% by weight, respectively.

17. The photoluminescent composition of claim 15, wherein the photoluminescent pigment is approximately 25% by weight and the binder mix is approximately 75% % by weight.

18. A method of marking trails and the like in the wilderness to glow in the dark for nighttime wilderness orientation, comprising:
a) mixing a photoluminescent pigment and a binder hardenable with moisture;
b) applying the mixture onto an outdoor object; and
c) charging the applied outdoor mixture with ultraviolet light for the mixture to glow in the dark.
